(19) United States
(12) Patent Application Publication
(10) Pub. No.: US 2006/0071302 A1
(43) Pub. Date: Apr. 6, 2006

(54) Fluid injection devices and fabrication methods thereof

(75) Inventors: Wei-Lin Chen, Taipei (TW); Hung-Sheng Hu, Kaohsiung (TW); Der-Rong Shyn, Chiayi County (TW)

Correspondence Address: BIRCH STEWART KOLASCH & BIRCH, PO BOX 747, FALLS CHURCH, VA, 22040-0747, US

(73) Assignee: BENQ CORPORATON

(21) Appl. No.: 11/242,780

(22) Filed: Oct. 5, 2005

(30) Foreign Application Priority Data
Oct. 6, 2004 (TW) 93130205

(51) Int. Cl. H01L 23/58

(52) U.S. Cl. 257/639

(57) ABSTRACT

Fluid injection devices and fabrication methods thereof. A first structural layer is disposed on a substrate. A fluid chamber is disposed between the substrate and the first structural layer. At least one bubble generator is disposed on the first structural layer and on the opposite side of the fluid chamber. A first passivation layer is disposed on the first structural layer covering the bubble generator. A second structural layer is disposed on the passivation layer. A second passivation layer is conformably deposited on the second passivation layer. A nozzle adjacent to the bubble generator passes through the second passivation layer, the second structural layer, the first passivation layer, and the first structural layer communicating the fluid chamber, wherein the sidewall of the nozzle is made of the first structural, the first passivation layer and the second passivation layer.

### BACKGROUND

The invention relates to fluid injection devices and fabrication methods thereof, and more particularly, to fluid injection devices with substantially planar surface and anticorrosion capability and fabrication methods thereof.

Typically, fluid injection devices are employed in inkjet printers, fuel injectors, biomedical chips and other devices. Among inkjet printers presently known and used, injection by thermally driven bubbles has been most successful due to its reliability, simplicity and relatively low cost.

FIG. 1 is a cross section of a conventional monolithic fluid injector 1 disclosed in U.S. Pat. No. 6,102,530, the entirety of which is hereby incorporated by reference. A structural layer 12 is formed on a silicon substrate 10. A fluid chamber 14 is formed between the silicon substrate 10 and the structural layer 12 to receive fluid 26. A first heater 20 and a second heater 22 are disposed on the structural layer 12. The first heater 20 generates a first bubble 30 in the chamber 14, and the second heater 22 generates a second bubble 32 in the chamber 14 to inject the fluid 26 from the chamber 14.

Conventional monolithic fluid injectors using a bubble as a virtual valve are advantageous due to reliability, high performance, high nozzle density and low heat loss. As inkjet chambers are integrated in a monolithic silicon wafer and arranged in a tight array for high device spatial resolution, no additional nozzle plate is required for assembly.

The structural layer 12 of the conventional monolithic fluid injector 1 comprises low stress silicon nitride. The lifetime of the injector 1 is, however, determined by thickness of the structural layer. Moreover, a droplet may deviate from the desired direction due to structural layer insufficient thickness. Additionally, since heaters 21 and 22 are located on the structural layer, the heat generated by the heaters 22 and 23 may pass through the structural layer into the chamber, causing crosstalk and disturbing the operating frequency.

It is therefore desirable to provide a fluid injection device with a strengthened structural layer capable of effectively dissipating heat. FIG. 2 is a cross section of a conventional fluid injection device 100. The conventional fluid injection device 100 is covered by a metal layer 140 over the structural layer 130. Since the metal layer 140 has excellent thermal dissipation capability, the structural layer is strengthened by the metal layer and residual heat is conducted and dissipated effectively. Typically, the metal layer 140 is made of gold, platinum, nickel, or nickel based alloy. An electroplated gold layer with a rough surface can, however, cause fluid residue to accumulate on the nozzle causing the trajectory of droplet flight to deviate. Conversely, nickel or nickel based alloys with a smoother surface, however, cannot resist fluid corrosion. Poor anticorrosion capability can be less reliability and have reduced product lifetime.

U.S. Pat. No. 6,155,676, the entirety of which is hereby incorporated by reference, discloses a conventional bottom shooting injection device with a ruthenium (Ru) layer covering the nickel or nickel based alloy layer. Considering fabrication methods for monolithic fluid injection devices, however, it is difficult to form a Ru layer covering the nickel or nickel based alloy layer.

### SUMMARY

Fluid injection devices and fabrication methods thereof are provided. By employing a second structural layer with a substantially planar surface and a second passivation layer with anticorrosion capability, injection performance can be improved and product lifetime can be extended.

Accordingly, the invention provides a fluid injection device. A first structural layer is disposed on a substrate. A fluid chamber is disposed between the substrate and the first structural layer. At least one bubble generator is disposed on the first structural layer and on the opposite side of the fluid chamber. A first passivation layer is disposed on the first structural layer covering the bubble generator. A second structural layer is disposed on the passivation layer. A second passivation layer is conformably deposited on the second passivation layer. A nozzle adjacent to the bubble generator passes through the second passivation layer, the second structural layer, the first passivation layer, and the first structural layer communicating the fluid chamber. The sidewall of the nozzle is made of the first structural layer, the first passivation layer and the second passivation layer.

The invention provides a method for fabricating a fluid injection device. A patterned sacrificial layer is formed on a substrate. A patterned first structural layer is formed on the substrate covering the sacrificial layer. At least one fluid actuator is formed on the first structural layer. A first passivation layer is formed on the first structural covering the fluid actuator. An under bump metal (UBM) layer is formed covering the first passivation layer. A patterned first photoresist is formed at the predetermined nozzle site exposing the UBM layer. A second structural layer is formed on the UBM layer. The first photoresist is removed, thereby creating an opening at the predetermined nozzle site exposing the UBM layer. A patterned second photoresist is formed on a portion of the UBM layer. The exposed UBM layer in the opening is removed. The second photoresist is removed. A patterned third photoresist is formed on a portion of the UBM layer. A second passivation layer is conformably formed on the second structural layer and the exposed UBM layer. The third photoresist and the underlying UBM layer are removed. A portion of the bottom of the substrate is removed, thereby creating a fluid channel in the substrate and exposing the sacrificial layer. The sacrificial layer is removed to form a fluid chamber. The first passivation layer and the first structural layer are etched to create a nozzle adjacent to the fluid actuator and communicating with the fluid chamber.

### DESCRIPTION OF THE DRAWINGS

The invention can be more fully understood by reading the subsequent detailed description in conjunction with the examples and references made to the accompanying drawings, wherein:

FIG. 1 is a schematic view of a conventional fluid injection device;

FIG. 2 is a cross section of a conventional fluid injection device; and

FIGS. 3A-3H are cross sections of an exemplary method of fabricating a fluid injection device with substantially planar surface and anticorrosion capability.

### DETAILED DESCRIPTION

The invention provides a fluid injection device with substantially planar surfaces and anticorrosion capability against ink and fabrication methods thereof. Two metal layers, for example, are adopted to change the surface characteristics of the fluid injection devices. The two metal layers comprising substantially planar surfaces and anticorrosion capability, respectively are employed to improve injection efficiency, prolong injection device life, and enhance injection quality.

Reference will now be made in detail to the preferred embodiments of fluid injection devices with substantially planar surfaces and anticorrosion capability against ink and fabrication methods thereof, examples of which are illustrated in the accompanying drawings.

The fluid injector 100 comprises a base 110 having a fluid chamber 113 in a substrate 111, a first structural layer 112 disposed on the substrate, at least one bubble generator 120, such as heater, formed on the structural layer, and a first passivation layer 130 disposed on the first structural layer covering the bubble generator 120. A second structural layer is disposed on the first passivation layer. A second passivation layer is disposed on the second structural layer. A nozzle is created through the second passivation layer, the second structural layer, the first passivation layer 130 and the first structural layer 112, communicating with the chamber. The sidewalls of the nozzle are made of the first structural layer, the first passivation layer and the second passivation layer.

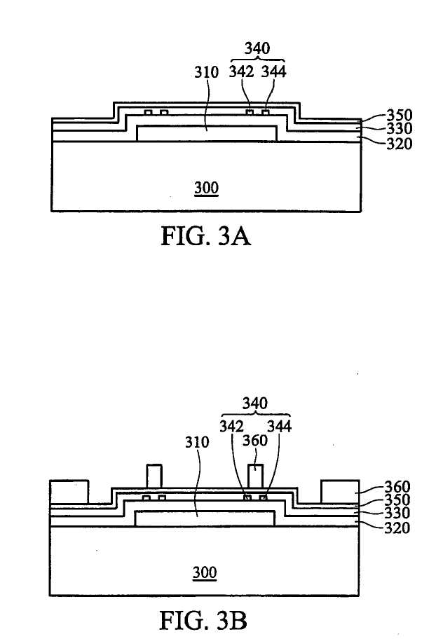

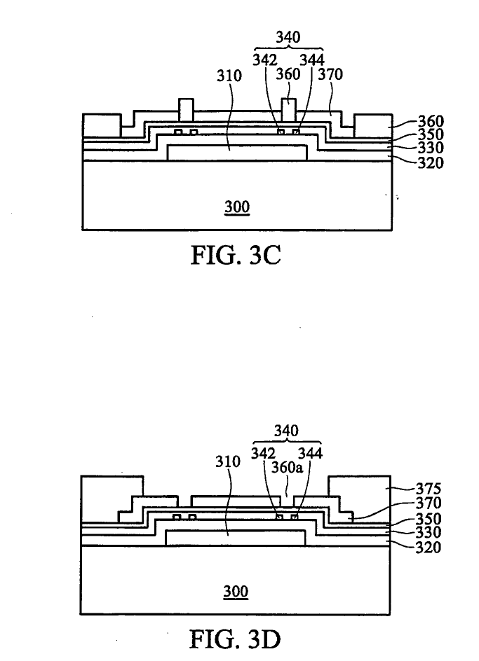

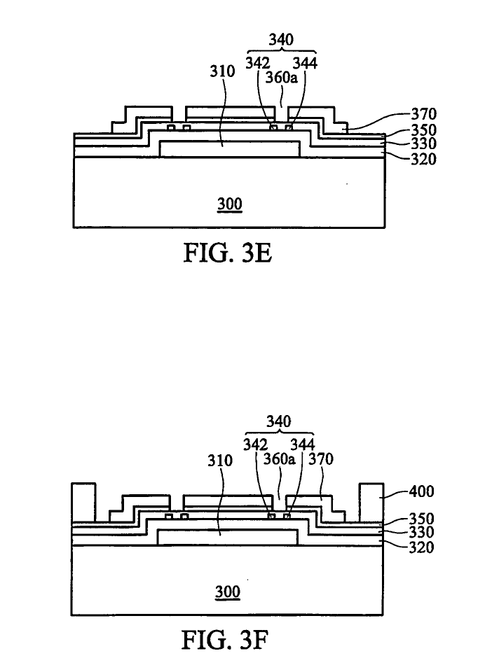

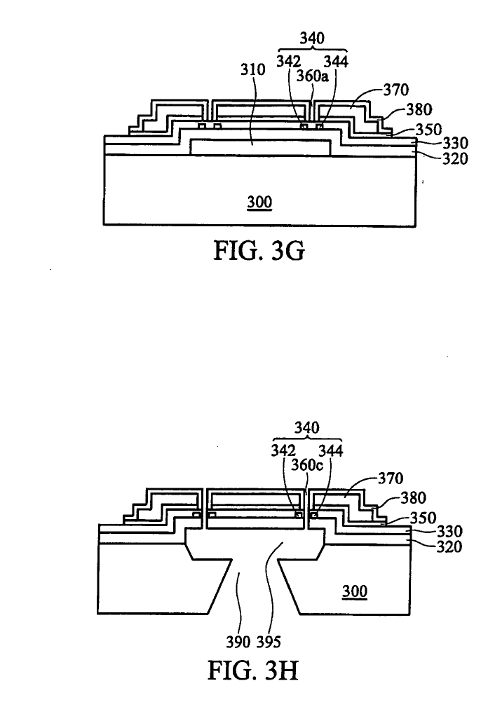

FIGS. 3A-3H are cross sections of an exemplary method of fabricating a fluid injection device with substantially planar surfaces and anticorrosion capability against ink. Referring to FIG. 3A, a substrate 300 such as single crystalline silicon wafer is provided. A patterned sacrificial layer 310 is formed on the substrate 300. The sacrificial layer 310 is made of silicon oxide, borophosphosilicate glass (BPSG), or phosphosilicate glass (PSG), for example. The sacrificial layer 310 can be deposited by chemical vapor deposition (CVD) or low pressure chemical vapor deposition (LPCVD). Next, a patterned first structural layer 320 is conformably formed on the substrate 300 covering the sacrificial layer 310. The first structural layer 320 can be made of low stress silicon oxynitride (SiON) or low stress silicon nitride (Si₃N₄) deposited by CVD or LPCVD. The stress of the first structural layer 320 can be, for example, approximately 50 to 300 MPa. At least one fluid actuator 340 such as a bubble generator is subsequently formed on the first structural layer 320. The bubble generators 340 can be made of a resistive layer, preferably comprising HfB₂, TaAl, TaN, or TiN. The bubble generators 340 can be deposited by physical vapor deposition (PVD), such as evaporation, sputtering, or reactive sputtering. Next, a first passivation layer 330 is formed on the first structural layer 320 covering the bubble generators 340. The first passivation layer 330 can be made of a silicon oxide layer deposited by CVD or LPCVD, for example. Next, an under bump metal (UBM) layer 350 can be formed on the first passivation layer 330. The UBM layer 350 can be a thin TiW/Au layer or a thin Cr/Cu layer.

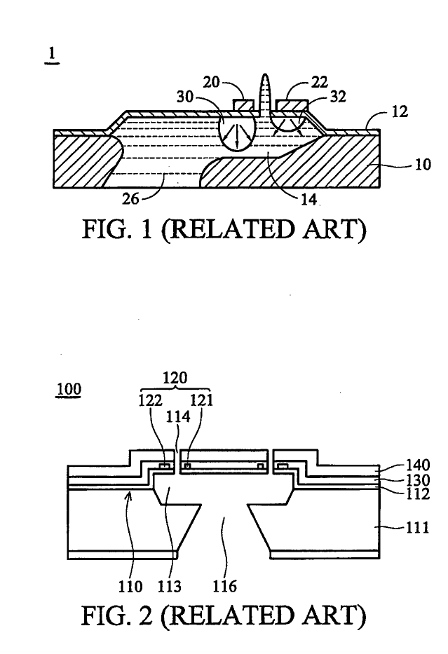

According to the invention, the bubble generators 340 may also comprise a first heater 342 and a second heater 344, for example. The first heater 342 generates a first bubble (as shown in FIG. 1) in the chamber, and the second heater 344 generates a second bubble (as shown in FIG. 1) in the chamber to inject the fluid from the chamber.

An embodiment of a method for fabricating the fluid injection device may further comprise forming a signal transmitting circuit (not shown) disposed between the first structural layer 320 and first passivation layer 330 connecting the bubble generators 340. The signal transmitting circuit can be made of conductive layer, such as aluminum (Al), copper (Cu), Al—Cu alloy, or other conductive materials deposited by PVD, for example.

Referring to FIG. 3B, a patterned first photoresist 360 is lithographically formed on the UBM layer 350 with an opening exposing a predetermined nozzle site.

Referring to FIG. 3C, a second structural layer 370 is formed on the UBM layer 350. The second structural layer 370 comprises a smooth surface preventing fluid residue from accumulating on the nozzle. The droplet flying trajectory deviation can also be prevented, thereby improving injection quality. The second structural layer 370 is made of Ni, Ni-based alloy, cu or alloys thereof deposited by electroplating, electro-forming, electroless plating, physical vapor deposition or chemical vapor deposition.

Referring to FIG. 3D, the first patterned photoresist 360 is subsequently removed, exposing the UBM layer 350 in the opening 360a. A second patterned photoresist 375 is formed at the peripheral of the fluid injection device.

Referring to FIG. 3E, the exposed UBM layer 350 in the opening 360a is subsequently removed by wet etching, for example. Next, the second photoresist 375 is removed.

Referring to FIG. 3F, a third photoresist 400 is formed at the peripheral of the fluid injection device covering portion of the UBM layer 350.

Referring to FIG. 3G, a second passivation layer 380 is conformably formed on the second structural layer 370 and the UBM layer 350. The second passivation layer 380 is made of Au, Au-based alloy, Pd, Pt or other noble metals deposited by electroplating, electro-forming, or electroless plating. Optionally, an adhesion layer (not shown) can further formed between the second structural layer 370 and the second passivation layer 380, for example.

Referring to FIG. 3H, the back of the substrate 300 is etched forming a fluid channel 390 in the substrate 300 and exposing the sacrificial layer 310. The sacrificial layer 310 is subsequently removed and enlarged, forming a fluid chamber 395.

Next, a nozzle 360c is formed by etching the first passivation layer 330 and the first structural layer 320 along the opening 360b. The nozzle 360c is adjacent to the bubble generators 340 communicating with the fluid chamber 395.

As illustrated in FIG. 3H, an exemplary embodiment of the invention providing a fluid injector 100 with a first metal layer 140 may substantially strengthen the fluid injector, thermally dissipate residual heat, and by the planar surfaces thereof prevent fluid residue from accumulating on the surface of nozzles, resulting in consistent injection, stabilizing the trajectory of droplet flight, and increasing the operating frequency. The fluid injector 100 further comprises a second metal layer such as Au, Au-based alloy, Pd, Pt or other noble metals with anticorrosion capability, thereby improving reliability and lifetime of the fluid injection device.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A fluid injection device, comprising:
a substrate;
a first structural layer disposed on the substrate;
a fluid chamber between the substrate and the first structural layer;
at least one bubble generator disposed on the first structural layer and on the opposite side of the fluid chamber;
a first passivation layer disposed on the first structural layer covering the bubble generator;
a second structural layer disposed on the first passivation layer;
a second passivation layer conformably formed on the second structural layer; and
a nozzle adjacent to the bubble generator and passing through the second passivation layer, the second structural layer, the first passivation layer, and the first structural layer communicating the fluid chamber;
wherein a sidewall of the nozzle is made of the first structural layer, the first passivation layer and the second passivation layer.

2. The fluid injection device as claimed in claim 1, wherein the bubble generator comprises resistive heaters.

3. The fluid injection device as claimed in claim 2, wherein the resistive heaters comprise:
a first heater disposed on the structural layer outside the fluid chamber to generate a first bubble in the fluid chamber; and
a second heater disposed on the structural layer outside the fluid chamber to generate a second bubble in the fluid chamber.

4. The fluid injection device as claimed in claim 1, wherein the first structural layer comprises a low stress silicon nitride layer or a low stress silicon oxynitride layer.

5. The fluid injection device as claimed in claim 1, wherein the first passivation layer comprises a silicon oxide layer.

6. The fluid injection device as claimed in claim 1, wherein the second structural layer comprises a substantially planar surface.

7. The fluid injection device as claimed in claim 6, wherein the second structural layer comprises Ni, Cu, or alloys thereof.

8. The fluid injection device as claimed in claim 1, wherein the second passivation layer has anticorrosion capability.

9. The fluid injection device as claimed in claim 8, wherein the second passivation layer comprises Ag, Pd, Pt, or alloys thereof.

10. A method for fabricating a fluid injection device, comprising:
providing a substrate;
forming a patterned sacrificial layer on the substrate;
forming a patterned first structural layer on the substrate covering the sacrificial layer;
forming at least one fluid actuator on the first structural layer;
forming a first passivation layer on the first structural covering the fluid actuator;
forming an under bump metal (UBM) layer covering the first passivation layer;
forming a patterned first photoresist at the predetermined nozzle site exposing the UBM layer;
forming a second structural layer on the UBM layer;
removing the first photoresist creating an opening at the predetermined nozzle site exposing the UBM layer;
forming a patterned second photoresist on a portion of the UBM layer;
removing the exposed UBM layer in the opening;
removing the second photoresist;
forming a patterned third photoresist on a portion of the UBM layer;
conformably forming a second passivation layer on the second structural layer and the exposed UBM layer;
removing the third photoresist and the underlying UBM layer;
removing a portion of the bottom of the substrate, thereby creating a fluid channel in the substrate and exposing the sacrificial layer;
removing the sacrificial layer to form a fluid chamber; and
etching the first passivation layer, and the first structural layer to create a nozzle adjacent to the fluid actuator and communicating with the fluid chamber.

11. The method as claimed in claim 10, wherein the first structural layer comprises a low stress silicon nitride layer or a low stress silicon oxynitride layer.

12. The method as claimed in claim 10, wherein the first passivation layer comprises a silicon oxide layer.

13. The method as claimed in claim 10, wherein the second structural layer comprises a substantially planar surface.

14. The method as claimed in claim 13, wherein the second structural layer comprises Ni, Cu, or alloys thereof.

15. The method as claimed in claim 13, wherein the second structural layer is formed by electroplating, electroforming, or electroless plating.

16. The method as claimed in claim 10, wherein the second passivation layer has anticorrosion function.

17. The method as claimed in claim 16, wherein the second passivation layer comprises Ag, Pd, Pt, or alloys thereof.

18. The method as claimed in claim 16, wherein the second passivation layer is formed by electroplating, electroforming, or electroless plating.
